(19) United States
(12) Patent Application Publication
(10) Pub. No.: US 2012/0138452 A1
(43) Pub. Date: Jun. 7, 2012

(54) Method and Apparatus for Super-High Rate Deposition

(75) Inventor: Andre Anders, El Cerrito, CA (US)

(73) Assignee: The Regents of the University of California, Oakland, CA (US)

(21) Appl. No.: 13/264,692

(22) PCT Filed: Apr. 13, 2010
(86) PCT No.: PCT/US10/30908

§ 371 Date: Nov. 7, 2011

Related U.S. Application Data
(60) Provisional application No. 61/170,374, filed on Apr. 17, 2009.
(60) Provisional application No. 61/226,055, filed on Jul. 16, 2009.

(51) Int. Cl. C23C 14/35

(52) U.S. Cl. 204/192.13; 204/298.03

(57) ABSTRACT

A method and apparatus for achieving very high deposition rate magnetron sputtering wherein the surface of a target and especially the race track zone area of the target, in one embodiment may be heated to such a degree that the target material approaches the melting point and sublimation sets in. Controlled heating is achieved primarily through the monitoring of the temperature of the target material and with the aid of a processor subsequently controlling the target temperature by adjustment of the power being inputted to the target. This controlled heating to the sublimation point is particularly effecting in high deposition rate metal coating of parts when used in conjunction with HIPIMS deposition. The apparatus for controlling temperature of the target in one embodiment includes a thermocouple, which is electronically connected to a controller or microcomputer which is programmed to control the power of the pulse to the target, and the duty cycle of the power pulses as the primary means for regulating the temperature of the system.

### CROSS REFERENCE TO RELATED APPLICATIONS

This application claims priority to PCT Application PCT/US2010/030908, filed Apr. 13, 2010, which in turn claims priority to Provisional U.S. Patent Application 61/170,374 filed Apr. 17, 2009, for Method and Apparatus for Super-High Rate Deposition, as well as to Provisional U.S. Patent Application 61/226,055 filed Jul. 16, 2009, of the same title, Andre Anders the named inventor in both applications, each of which is incorporated herein as if fully set out in its entirety.

### STATEMENT OF GOVERNMENTAL SUPPORT

The invention described and claimed herein was made in part utilizing funds supplied by the U.S. Department of Energy under Contract No. DE-ACO2-05CH11231. The government has certain rights in this invention.

### BACKGROUND OF THE INVENTION

1. Field of the Invention

This invention relates generally to magnetron sputter deposition, and, more specifically a method and apparatus for the super high rate sputter deposition wherein the magnetron target material to be sputtered is heated to near its melting point in one embodiment, and to or above its melting point in another, and to a novel apparatus for practicing the method of this invention incorporating integrated temperature management systems.

2. Description of the Related Art

Ionized sputtering was an important step first performed in the early 1990s to improve step coverage in the manufacture of semiconductor chips and enabled via filling for integrated circuits. The general approach was to add a radio frequency ionization stage to the magnetron. The concept of ionized sputtering experienced a revival in recent years, but with a different approach based on pulsing a magnetron source with very high power at a relatively low duty cycle. The new technology is now generally referred to as high power impulse magnetron sputtering (HIPIMS).

High power impulse magnetron sputtering (HIPIMS) to many presents a new paradigm in sputtering. Operation at high power leads to partial to near complete ionization of sputtered target atoms. Some if not most of these ionized atoms are directed back to the target surface to further accelerate sputtering rates. Those ionized atoms that are not directed back to the target can impact the substrate being coated with greater energies in the case where the substrate is biased relative to the plasma. The ionization of the sputtered material thus opens significant opportunities for substrate-coating interface engineering and tailoring of film growth and resulting properties as has been reported in the literature.

HIPIMS is an interesting addition to the family of sputtering technologies. It is characterized by a very high power density at the target, exceeding “conventional” power densities by about two orders of magnitude or more. Of course, such “abuse” of a magnetron target would overheat the device if the duty cycle was high, and therefore HIPIMS has heretofore been used with low duty cycles.

While process parameters of HIPIMS have the potential to improve film quality and adhesion, deposition rates, normalized to the average power, under most circumstances is substantially reduced compared with equivalent DC power sputtering deposition rates. Since deposition rates are important for productivity in manufacturing, and ultimately for profitability, this decrease in deposition rate is of significant concern.

Previously, as reported by Chistyakov in US patent U.S. Pat. No. 6,896,773, very high deposition rates can be achieved using high power pulses of the appropriate power level and pulse duration. As observed by the patentee, if the energy delivered to the target is high enough, the “explosive energy at the target surface results in a sputtering yield that increases exponentially.” Here, Chistyakov suggests that the rapid increase in temperature at the target source causes the surface layer to evaporate and be sputtered at a very high rate. However, he also notes that the high power pulse generates thermal energy into only a shallow depth of the target so as not to substantially increase the target's average temperature, thus avoiding damage to the target. Though not specifically stated, the concern would be that thermal overloading of the target could lead to melting of the target, and/or demagnetization of the magnetron's magnets.

How Chistyakov is able to confine the heating of the target to only a shallow depth is not explained. One can infer that he either limits the power of each pulse via its amplitude and length, and/or decreases the duty cycle of the pulse. In addition, though not stated, Chistyakov may provide cooling to the target as well, as cooling capabilities are common to commercially available sputtering systems, the most frequently used cooling medium being water.

As a drawback to Chistyakov, there is no discussion as to how temperature is to be controlled. Because the rate of deposition is so dependent on target temperature, when the temperature is, for example close to the melting point, one would want to both know what temperatures are being encountered, and whether or not these temperatures were being consistent one pulse to the other in order to maximize uniformity of deposition. Required would be some sort of temperature measurement capability for providing target temperature information in order to make sure that (a) the target is not melting (if the system configuration cannot accommodate liquid target material), and (b) a controlled deposition rate are being realized. At best, Chistyakov does not provide temperature control, thus is not able to assure uniformity of deposition rate other than by empirical experience, while at the same time running the risk of damaging the apparatus itself.

### BRIEF SUMMARY OF THE INVENTION

By this invention an apparatus is described wherein the heat to the target is controlled such that HIPIMS deposition rates may in fact be uniformly enhanced to the point they exceed typical DC rates, if the surface of the target, and especially the race track zone area is allowed to be heated to such a degree that the target material approaches the melting point and sublimation sets in, while at the same time, in one embodiment, not cooling the material so that its temperature increases above the melting point and evaporation may take place in as well. More specifically, temperature control is achieved through a thermal management regime in which a thermo couple is used to monitor target temperature, and provide the necessary information to a controller or computer for simultaneously regulating the amount of power being delivered to the target, power controlled for example, by changing voltage, current, or pulse time, or a combination of one or more of these variables.

The magnetron can be empirically operated with the target at high temperature such that sublimation contributes to the flux of atoms from the target surface. In a preferred embodiment, the thermocouple or an optical temperature senor (pyrometer) is used to actively manage the power such that the target operates at a desired temperature. With the aid of appropriate electronic controllers, a feedback loop can be established such that the target temperature remains within a narrow temperature range by influencing the magnetron power through the reading of the temperature sensor, thereby affording control of the total flux of atoms from the surface. Depending on the target material and temperatures reached, the flux may be dominated by the sputtering process, or by sublimation and/or evaporation.

### BRIEF DESCRIPTION OF THE DRAWINGS

The foregoing aspects and others will be readily appreciated by the skilled artisan from the following description of illustrative embodiments when read in conjunction with the accompanying drawings. The Figures are as depicted in the attached materials.

FIG. 1 is a cross sectional view of a planar magnetron designed for hot target sputtering.

FIG. 2 is a cross sectional view of a modified planar magnetron for use with a liquefied target material.

FIG. 3 is a cross sectional view of another hybrid system provided with integrated heaters, and designed for a use with a liquefied target material.

FIG. 4 is cross sectional view of a dual hybrid source based on a dual magnetron configuration.

FIG. 5 illustrates another embodiment of a hybrid sputtering and evaporation source, incorporating an electron beam magnetically steered to the target.

### DETAILED DESCRIPTION OF THE INVENTION

The several embodiments of the invention are described and illustrated as set forth below.

Fundamental to the instant invention is the replacement of the usual target cooling (in almost all cases water-cooling) in magnetron sputtering by “integrated temperature management”, thereby creating a new hybrid apparatus and method based on the combination of sputtering and sublimation/evaporation, as supplemented by plasma generation. In this approach target temperature is controlled by controlling the power to the target, the temperature monitored and allowed to approach the melting temperature of the target material, where sublimation occurs. In the case of integrated temperature management with a HIPIMS process, one combines sublimation and magnetron sputtering with the formation of dense plasma formation, taking the best features of sublimation (very high rate) and HIPIMS (ion assisted plasma formation for film growth). As will be later discussed, the approach preferably includes HIPIMS but in other embodiments it can be practiced without the HIPIMS feature.

### Embodiment A

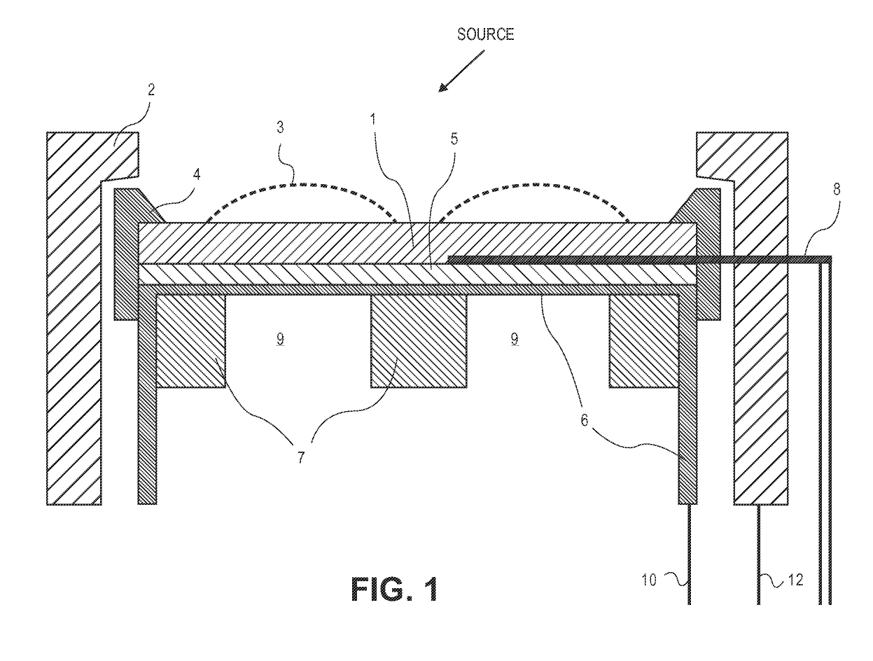

FIG. 1, the first embodiment, is a cross sectional view of a planar magnetron modified for hot target sputtering. Within a deposition chamber, not shown, is a magnetron Source comprising a target 1 made of the material to be sputtered/deposited onto a substrate. In the illustrated embodiment the substrate to be coated is mounted to the top of the chamber, and maintained at a negative potential relative to the ions of the plasma, whereby the sputtered and sublimated atoms move upwardly to coat the substrate. Target 1 is secured to a support stage 5 (which also acts as a thermal barrier) via clamps 4. In one embodiment, for target materials that require very high temperature to utilize the sublimation effect, the support stage can be made out of stainless steel, and is thereby thermally insulating. In contrast to a conventional magnetron, the thermal barrier provided by stage 5 allows one to operate the target at high temperature while keeping the magnetron magnets sufficiently cooled. Typically, support stage 5 may alternatively be made from tantalum, molybdenum, or tungsten.

Enclosure 6 to the backside of support stage 5, and external to the processing section of said chamber, includes a plurality of magnets 7, which create the necessary magnetic fields above the target to confine electrons and provide the conditions for their closed drift in the ionization zone, the magnetic fields represented by dashed lines 3. The magnets are surrounded by a coolant such as water, which flows through enclosure 6 and around the magnets through cavities 9. In this embodiment, impulse power for HIPIMS deposition is supplied through cable 10 to target 1, with cable 12 providing a positive charged voltage to anode 2, which surrounds the target. Where enclosure 6 and support stage 5 are sufficiently conductive, power can be delivered through enclosure 6 and stage 5 to the target, or separate electrical connection provided (not shown) to directly contact the target. Finally, the temperature of the target is measured by a temperature sensing device 8, which in one embodiment is a thermocouple which can be connected to a microcontroller, or a computer (not shown), the controller/computer programmed through a feedback loop to modify the power pulse to the target in response to the sensed temperature in order to maintain the temperature of the target at a preselected limit. In one embodiment that limit is near the melting point, whereby the erosion of the target (i.e. the density of the plasma) is enhanced by sublimation of target material from the target.

The Source has well controlled temperature zones. The hot zones include the target and anode while the cool zones include the mounting and the magnet assembly. The magnets need to remain in the working temperature range, which is clearly below the Curie temperature (that is, the temperature above which the permanent magnets lose their magnetization). For example, the working temperature for Nd—Fe—B magnets is up to 220° C. and the Curie temperature is between 310° C. and 340° C. depending on the composition. In most cases, where one uses water as a coolant, the coolant serves to keep the magnets well below this temperature. The magnets can be kept at a temperature between 0° C. and 100° C. Where the cooling zone is designed to operate at temperatures lower than 0° C., liquid nitrogen cooling can be used. For a design with temperatures higher than 100° C. for magnets capable of operating at much higher temperatures, oil or compressed gas (air) can be used as a coolant.

In one embodiment, a shutter (not shown) may be placed in the chamber, interposed between the target and the substrate. The providing of the shutter allows the operator to switch the source on, and reach a condition of thermal equilibrium before starting the actual deposition process. The presence of the shutter, can in the case where reactive gases are introduced into the deposition chamber, also prevent poisoning of the target surface prior to sputter deposition. By way of illustration, where a reactive gas such as nitrogen or oxygen is introduced into the chamber, the gas will interact at its surface with the target material (as well as the substrate) to “poison” the target. A poisoned target surface usually has a much lower sputter yield than the corresponding metallic target surface. In the case of a titanium target, in the presence of an inert gas alone, such as argon, a clean metallic surface is maintained. In the additional presence of oxygen, however, used in the formation of titanium oxide films on a substrate, oxides will also form on the surface of the titanium target. By introducing the reactive gas on the substrate side of the closed shutter, this poisoning effect on the target is thus significantly reduced.

In another embodiment, support stage 5 may be replaced by a thin gap (such as 1 mm), with target 1 supported in spaced relationship to enclosure 6 by short conducting posts disposed (in one embodiment) at the periphery of the target. In this configuration, process gas can penetrate into the volume defined by the space between target 1 and enclosure 6, but contributes very little to the heat transfer. Thus, the target is thermally well isolated, which improves energy efficiency, target 1 more easily brought to very high temperature by process power supplied through cable 10. In this embodiment it is to be understood that thermocouple 8 is attached to target 1.

Support stage 5 need not necessarily be made of a low heat conduction material, but merely must serve as a member that separates the high temperature zone from a lower temperature zone. Its design (thickness, material composition, etc.) will in part depend upon the intended use, and in turn upon the desired temperatures to which the target materials will be brought. Thus, support stage 5 must be capable of accommodating the heat gradients developed during chamber operation. Its heat conduction capacity should be large enough to allow the source to operate with an average power exceeding the average power values typical for magnetron sputtering Yet, in one embodiment, the support stage is formed of a material having a high heat conduction capacity, such as is the case for a Zn target, which sublimates at temperatures around 350° C. To reach and maintain such relatively low temperatures, it is important to remove process heat with active cooling. The other alternative, to reduce the average power to the target, will result in loss of productivity, which is contrary to the objects of this invention.

The temperature sensor may be a thermocouple disposed in a suitable housing, which allows for the monitoring of the temperature of the hot zone, and in particular the target temperature. Suitable thermo couples include those made by the Fluke Company under the brand name Fluke 80TK Thermocouple Module. Alternatively, a radiative thermo-sensor can be used such as the MM series made the Raytek Company. The placement for the temperature sensor as shown in FIG. 1 is suitable for those target materials that remain solid within the specified average power. The thermocouple may also be galvanically isolated such that the target can be at high negative bias while the thermocouple electronics can be maintained at near ground potential. Such galvanic isolation can be achieved via standard opto-couplers and/or fiber-optical data transmission.

In one embodiment of the invention, a gas supply can be incorporated into the source, in one embodiment similarly to the way it is done in Chistyakov's '773 patent. This can preferably be done by using the gap between cathode 1 (i.e., the target) and anode 2. Alternatively, the anode can be a gas manifold configured to supply gas evenly to the target region. The processing gas in magnetron sputtering is often a mixture of argon and a reactive gas like oxygen or nitrogen, especially where it is desired to form oxide films in the deposition process. Using an integrated gas supply system, one may advantageously supply argon (or other noble gas) and the reactive gas separately. Thus argon gas used in connection with plasma initiation is injected near the target to keep the target metallic, and the reactive gas supplied some distance (e.g. >1 cm) from the target. In the case where a shutter is employed, as discussed earlier, the reactive gas is preferably introduced on the target side of the shutter. In this manner, both a high sputtering rate and activation (excitation and ionization) of the gas can be obtained.

The magnetron Source of FIG. 1 is essentially axis-symmetric, with the target being a disk with circular shape when viewed from the top. The source may also be “linear” in the sense that the target appears as a rectangle when viewed from the top, with one side of the rectangle substantially longer than the other. Such “linear” magnetrons are well known to those skilled in the art.

Target and magnet assembly can be designed to move relative to each other. Accordingly, either (i) the target can be fixed with respect to a holder and the magnet assembly moved to improve target utilization and coatings uniformity or (ii), the magnet assembly is fixed with respect to a holder and the target moves. In one embodiment the target can be cylindrical, and rotated during deposition, such cylindrical magnetrons widely used for large area coatings for reactive sputtering. See for example U.S. Pat. No. 6,365,010, and for smaller, wafer-type substrates using pulsed sputtering see U.S. Pat. No. 6,413,382. Such designs, know in the art, do not per se constitute a part of the instant invention and are thus not further discussed herein.

Because the source, or at least parts of it, operate at elevated temperature, it may be prudent to add heat shields (not shown) to surround the source. However, it is to be appreciated that such shields are not essential to the operation and thermal management of the magnetron.

### Embodiment B

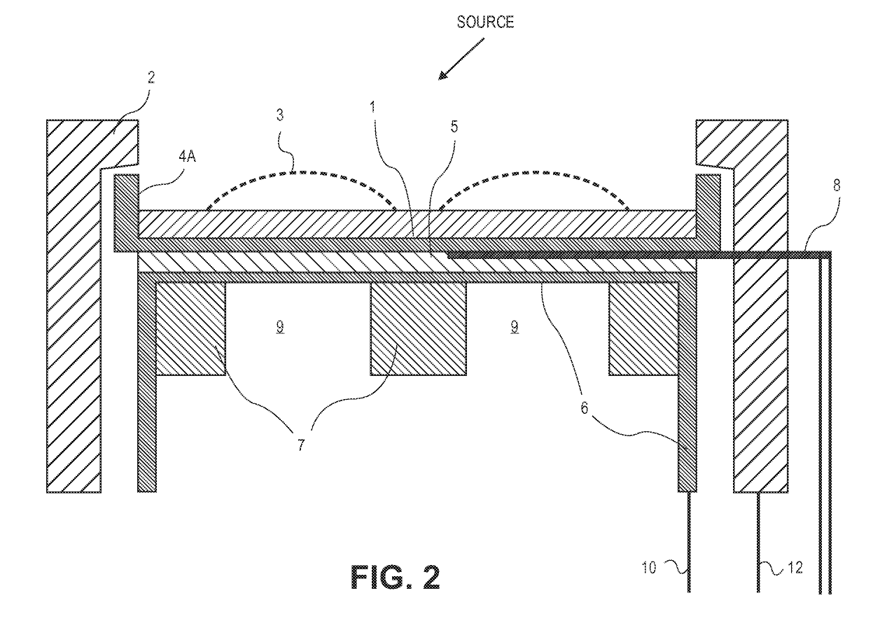

FIG. 2 is a cross section of a modified planar magnetron source where the target is to be heated to or above its melting temperature. Holder 4 of FIG. 1, in this embodiment, is replaced with a crucible 4a designed to contain the liquid target material, the liquid target solid at beginning of the process. Other numbered elements have the same function as those parts similarly numerically identified in FIG. 1.

In this embodiment, the temperature of the target is allowed to reach and exceed the melting temperature, which occurs readily with low melting temperature metals like Ga, In, Sn, Pb, Bi, Tl, Te, Sb, and Zn. As melted, evaporation of target material becomes a significant mode of transfer to the substrate, leading to even higher deposition rates that sublimation. While splattering could be of concern if the molten substrate were heated above its boiling point, given the large temperature range between melting and boiling, control of temperature to assure that the boiling point is not reached, is fairly simple, and thus the danger of splatter is not of much concern. In an application of this embodiment, zinc is of special interest due to it high vapor pressure and its utility in the formation of transparent conducting layers, with special application to the manufacture of transparent electronics. For a related discussion of liquid metal alloy sputtering, the reader is directed to Krutenat's U.S. Pat. No. 3,799,862, who intentionally heats a target material above its melting point. More importantly in the context of the instant invention, the flux of material from a liquid target is even more temperature sensitive compared to the flux from a still-solid target, and a controlled and well reproducible process requires even more control over the temperature. Yet, this 1970 era patent does not disclose a means for temperature control and feedback, inferentially suggesting that the process is empirically regulated.

It is noted that the preferred mode of sputtering is the HIPIMS mode. Self sputtering can be sustained beyond the threshold for runaway, which is given by Π≡αβγ_{SS}=1, where α is the ionization probability, β is the probability that the newly formed ion returns to the cathode (target), and γ is the self-sputtering yield, defined as the ratio of number of atoms removed from the target surface to the number of ions arriving to the target. By assisting the sputtering through sublimation from the solid target, or evaporation if from a liquid target, the value of γ is effectively enhanced because the flux of sputtered atoms is supplemented by a flux of sublimated or evaporated atoms. This makes the product Π larger and thereby lowers the threshold for runaway, which in turn is followed by increased power input and the formation of a plasma dominated by ionized target materials.

### Embodiment C

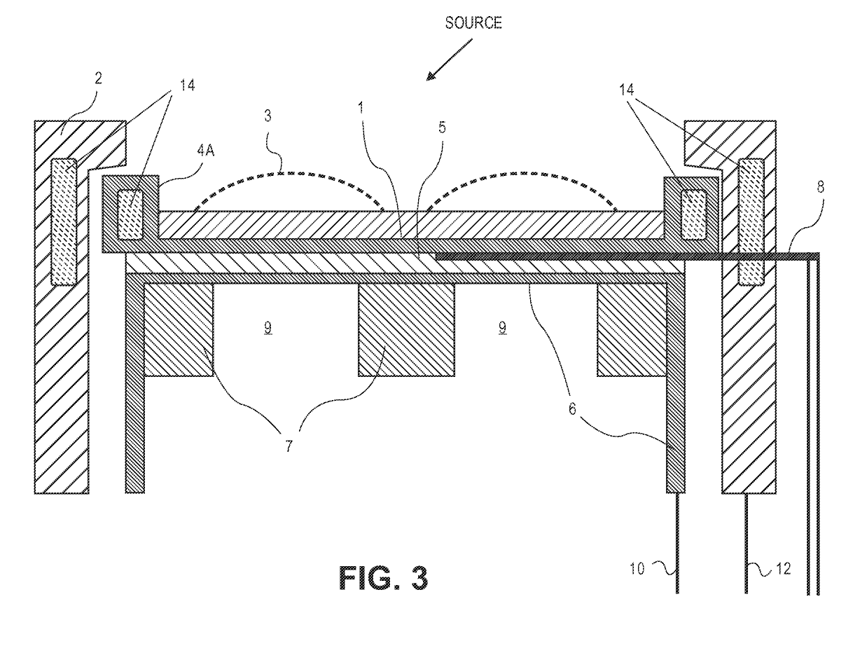

Temperature of the target may be controlled not just by adjusting of the power pulse duty cycle (or the voltage, or current of such power pulse) or by the changing of the temperature of the cooling fluids used with the magnet assembly. Additional temperature control may be realized by the incorporation of heating/cooling channels 14 into both the anode 2 and crucible 4a elements, as shown in FIG. 3. With both heating and cooling available, independent of process heating, a full integration of the target and anode temperature can be achieved. By this, it is meant that with both the target and anode temperature independently controllable, their temperature control can be integrated into the overall process. The temperature of the anode is important because a hot anode will re-sublimate the flux that comes from the target.

The incorporation of heaters affords at least two advantages: (1) it allows one to operate the hybrid source from the beginning at the desired temperature, not relying on process power alone to establish the desired target temperature; and (2) heating of the anode helps to prevent large built-up of target material on the anode which would occur if the anode was cold. A hot anode has the ability to re-evaporate/sublimate the material that otherwise would build up. Thus, heating of the anode assembly can be done such that the build-up is completely avoided. In this mode, the anode material is preferably be made of a material such as a refractory metal that has a high melting point and low vapor pressure.

### Embodiment D

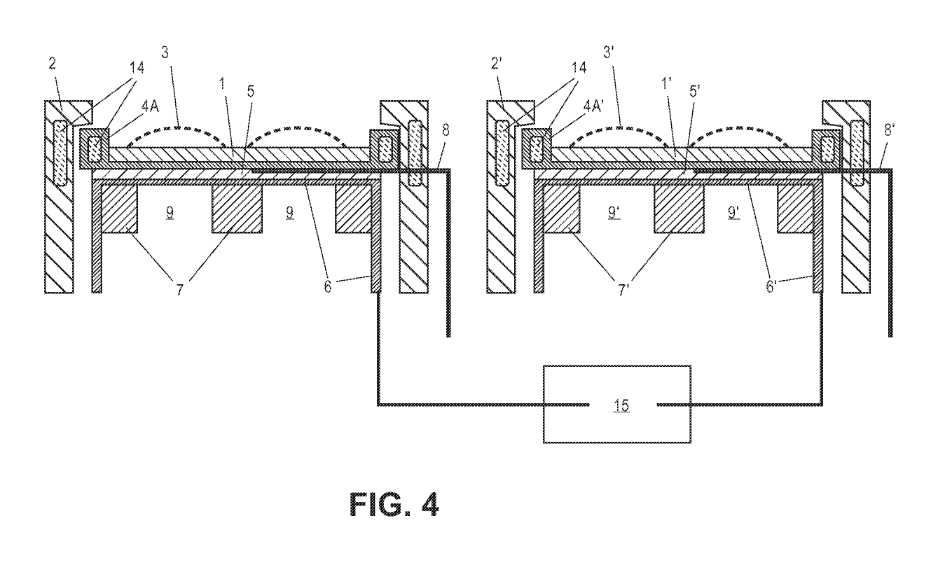

For reactive deposition, i.e. deposition in the presence of a reactive gas such as oxygen and nitrogen, it is desirable to avoid the “disappearing anode” effect, which occurs when the anode becomes covered with an insulating layer. For example, if the target is Ti or Al, and the reactive gas is oxygen, the resulting films that will be formed are TiO₂ and Al₂O₃, respectively, which are insulating. In this alternative embodiment, two sources (such as the embodiment of FIG. 3) can be assembled to form a pair, as shown in FIG. 4, and connected to a power supply 15 such that at a given moment in time the target of source No. 1 is the cathode and the target of source No. 2 is the anode. At another, well defined time later, the functions are reversed. That is, the target lof the first source is the anode and the target of the second source is the cathode. Then their electrical roles are reversed. Power supply 15 can be a dual magnetron supply in the sense that it provides AC power, or HIPIMS pulses with alternating polarity to both sources. Since the removal of surface atoms “cleans” the surface of the target, the target can maintain its electrical function (there being no insulating layer buildup serving to hide the electrode behind such a layer. In one embodiment, the two sources are positioned in the same chamber, thus affording the capability for coating larger surfaces. To improve the uniformity of the coating the substrate can also be moved back and forth within the chamber. Of note in FIG. 4, with no power delivered to former anode 2, it now merely acts as a shield to other components within the chamber, i.e. the item does not form an active part of the electrical circuit.

While in most cases one would select the same material for both sources, in the arrangement of this embodiment the possibility is presented of using different target materials. The integrated temperature management feature can be adjusted individually for the sources to accommodate or compensate for differences in the materials behavior and rates of erosion. For example, one could use Zn in one of the sources, and Aluminum-doped Zn in the other. By adjusting the temperature ratio of the sources, one can adjust the amount of Al that is brought to the aluminum-doped zinc oxide (when the system is operated with oxygen in the gas environment to form the oxide on the substrate).

### Embodiment E

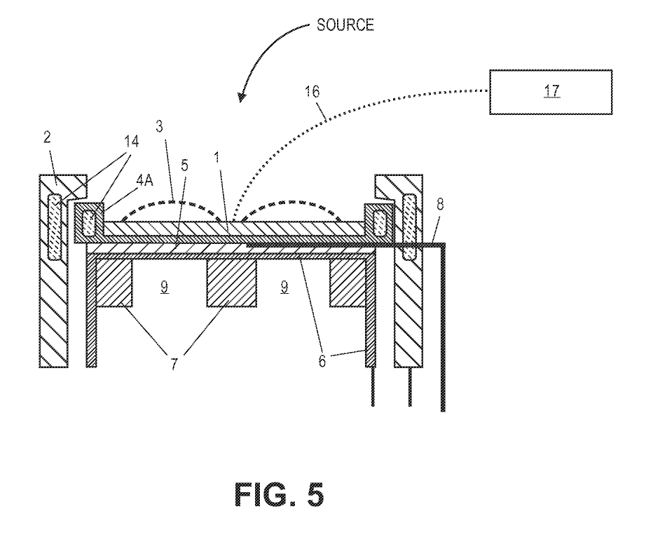

In yet still another embodiment, heat can further be added to the system by e-beam heating as it is typically done with e-beam evaporators, such a device illustrated in cross section in FIG. 5. Therein, electron gun 17 provides an electron beam 16 that is magnetically steered to the target. It should be noted that the curvature of the beam is due to a magnetic field, and that the magnetron's magnetic field may be used to help steer the e-beam towards the target. For this to occur, the magnetic field is preferably unbalanced and may be supplemented by an external field not generated by the magnet assembly shown in the Figure. The electron gyration radius becomes very small (millimeters or less) when considering the field strength over the racetrack. Therefore, it will be more practical to inject the electrons into a region where the magnetic field lines are essentially perpendicular to the target, which is generally near the center of the target.

### Methods of Operation

In one method, in a first step the Source chamber is evacuated, process gases introduced, and a negative bias applied to the target, as typically done with conventional magnetron sputtering systems. This negative bias of the target is with respect to the anode, which in most cases is connected to a ground potential, although this is not a necessity for the discharge to operate. The bias can be applied as DC, pulsed-DC, RF, or in high power pulses as is the case with HIPIMS processing, the latter being preferred due to dense plasma production that comes with the use of HIPIMS. A further discussion of the use of HIPIMS can be found in Applicant's papers further described as A. Anders, J. Andersson, and A. Ehiasarian, “High power impulse magnetron sputtering: Current-voltage-time characteristics indicate the onset of sustained self-sputtering,” J. Appl. Phys., vol. 102, pp. 113303-1-11, 2007, and J. Andersson and A. Anders, “Self-sputtering far above the runaway threshold: an extraordinary metal ion generator,” Phys. Rev. Lett., vol. 102, pp. 045003-01-04, 2009. A shutter, if available, may be kept closed until the source reaches equilibrium. The substrate is positioned, typically at 1-5 times the characteristic size of the target (which is the spacing between the so-called “racetracks”, i.e. the zones of most intense sputtering), and the shutter opened to allow deposition to begin. The substrate may be moved relative to the source in order to improve the uniformity of the coating. The temperature of the target is monitored and the power to the target adjusted based on the obtained temperature information.

When heaters to the cathode (i.e., the target) and anode are provided, the procedure can include preheating of the source before the negative bias to the target is applied and the discharge started. This may have the advantage that the discharge is operating primarily in the vapor of the target from the start. For example, when the shutter is closed and the source is preheated, a high vapor pressure material such as zinc (Zn) produces a vapor of appreciable pressure. By way of illustration, if the source is heated to 340° C., the zinc vapor has a pressure of 1 Pa (7.5 millitorr), a typical pressure for magnetron operation.

The temperature reading from a thermocouple or optical temperature sensor is used as in input signal to a signal processing unit, such PLC (programmable logic controller) or equivalent computer, and used to adjust to signals that control the process power supply output. Modern power supplies are equipped with interfaces that allow communication with a PLC or equivalent computer, and the PLC's signal will adjust to power via either amplitude, pulse repetition rate, or pulse duration. For example, if the temperature sensor indicates that the temperature exceeds a predetermined upper temperature value, the PLC will send signals to the power supply to reduce the power via reducing its amplitude of current or voltage, reduce pulse duration, reduce pulse frequency, or a combination thereof. Should the measured temperature then go below a set minimum temperature, the PLC will accord increase those adjustable power parameters.

In a preferred embodiment, the magnetron discharge is a HIPIMS discharge, which generates a dense plasma of the target material. The HIPIMS process is known to deliver a high flux of thermal energy to the target, mostly through bombardment of the target by positive ions. The feedback control to the power can be conveniently applied to the pulse repetition rate while keeping the voltage and current of each pulse approximately the same. Alternatively, the control of the average power can be done through a reduction in the applied voltage which will lead to a reduction of the discharge current and hence the discharge power per pulse.

While HIPIMS processing results in maximum deposition rates, further enhancing the deposition rate by high temperature operation is also applicable to more conventional sputtering regimes using DC (direct current), MF-pulsed DC (medium-frequency pulsed direct current, or RF (radio frequency) sputtering. Here, however, the benefit of dense plasma formation and self-sputtering is not as effective as is the case with HIPIMS. That is, one deals with a process of enhanced rates but minimal plasma assistance.

In conclusion, the invention described herein provides a deposition method leading to substantially higher rates of deposition, the deposition conducted either in vacuum or in gas. These higher rates are obtained when the target is maintained at or near the melting point of the target material. Herein described has been an apparatus for carrying out of such a high rate deposition, but with control of the temperature of the target. In one embodiment, this invention can be used for the sputter deposition of zinc oxide (a transparent conductor) for use with solar panels. In another embodiment, this invention can be used for very high rate metallization of virtually any substrate for decorative, protective, or electronic applications.

The process of this invention is best suited for metal targets which sublime at relatively low temperatures. For example, zinc sublimates at about 380 C at a vapor pressure of 10⁻¹ Torr. Another metal suitable for this process is magnesium which sublimates at about 650 C at a vapor pressure of 1.5 Ton. In contrast, copper sublimates at about 1100 C. Thus requires much higher temperatures to sublimate, such high temperatures limiting the application of this invention to such target materials.

This invention has been described herein in considerable detail to provide those skilled in the art with information relevant to apply the novel principles and to construct and use such specialized components as are required. Thus, though the sensor in this application has been described as a thermocouple, other methods such as optical methods/sensors may be used to measure the temperature of the target material. Accordingly, it is to be understood that the invention can be carried out by different equipment, materials and devices, and that various modifications, both as to the equipment and operating procedures, can be accomplished without departing from the scope of the invention itself.

What I claim is:

1. In a magnetron sputtering chamber, a method for high rate deposition of a film onto a substrate by the sputtering of target material onto said substrate, said method including the steps of:
a. positioning both the substrate to be coated and the target material comprising a source of the material to be coated onto the substrate within a deposition chamber,
b. directing an electrical current of a set voltage from a power source to said target material,
c. monitoring the temperature of the target material using a temperature sensing device. and; thereafter,
d. maintaining the temperature of the target material at a predetermined level.

2. The method of claim 1 wherein the target material is maintained at a temperature below its melting point, such that sublimation of the surface atoms of the target material occurs.

3. The method of claim 1 including the further step of heating the substrate to above its melting temperature such that evaporation occurs as well.

4. The method of claim 1 wherein the electrical current is a pulsed current.

5. The method of claim 4 wherein the maintaining of the temperature of the target material is achieved by regulating either the current, voltage or both in order to control the power being directed to the target material.

6. The method of claim 5 wherein the power being directed to the target material is adjusted in response to the monitored temperature of said target material.

7. The method of claim 6 wherein the output from the temperature sensing device is converted into a digital signal, said digital signal sent to a processor which has been preprogrammed to adjust the power being delivered to target, to maintain the target at a predetermined temperature range, said processor issuing a signal to the power source in order to control the power delivered during the next power pulse.

8. The method of claim 6 wherein the pulsed power is HIPIMS pulsed.

9. The method of claim 1 further including active cooling of the target material.

10. An apparatus for high rate deposition of a film including a stage for supporting a substrate to be coated, a stage for supporting a target material, a thermal sensor in thermal communication with said target material, means for heating the said target material, and means for regulating the temperature of the target material by controlling the power to the target in response to the output from the thermal sensor.

11. The apparatus of claim 10 further including a shutter disposed between the target material and the substrate to be coated.

12. The apparatus of claim 11 further including an inlet for introduction of a reactive gas into the apparatus of claim 1, wherein the point of introduction is situated between the side of the shutter facing the substrate, and the substrate itself.
